(19) United States
(12) Patent Application Publication
(10) Pub. No.: US 2024/0276850 A1
(43) Pub. Date: Aug. 15, 2024

(54) DISPLAY PANEL AND MOBILE TERMINAL

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventor: Qiankun XU, Shenzhen, Guangdong (CN)

(21) Appl. No.: 18/568,598

(22) PCT Filed: Dec. 22, 2021
(86) PCT No.: PCT/CN2021/140452

§ 371 Date: Dec. 8, 2023

(30) Foreign Application Priority Data
Dec. 14, 2021 (CN) 202111528192.X

(51) Int. Cl. H10K 59/80; H10K 59/12; H10K 59/124; H10K 59/126

(52) U.S. Cl. CPC H10K 59/879; H10K 59/1201; H10K 59/124; H10K 59/126; H10K 59/873

(57) ABSTRACT

A display panel and a mobile terminal are provided. The display panel includes a substrate and a light-emitting device. The substrate has a viewing angle adjustment structure near a light exit side of the light-emitting device. The viewing angle adjustment structure includes a first refractive index layer having a plurality of grooves and a second refractive index layer having a plurality of protrusions. Each protrusion corresponds to each groove. A refractive index of the second refractive index layer is less than a refractive index of the first refractive index layer.

### FIELD OF INVENTION

The present disclosure relates to the field of display, and in particular, to a display panel and a mobile terminal.

### BACKGROUND OF INVENTION

In active matrix organic light emitting diode (AMOLED) type display panels, each pixel may be lighted up separately under the drive of thin film transistors. The drive method has the advantages of high brightness, high resolution, low power consumption, easy realization in colorization and large-area display, etc., and is a commonly used method at present.

At present, due to the limitations in the development of light-emitting materials, organic light emitting diode (OLED) display devices are relatively low in light exit efficiency and cannot achieve an actual production level. To this end, engineers have prepared OLED display devices in a cavity length between a cathode and an anode, thereby greatly improving the luminous efficiency of OLED display devices through a laser resonant cavity principle. However, with the introduction of resonant cavities, light emitted by OLED display devices tends to converge towards collimating properties of laser, resulting in poor viewing angles of OLED display devices with resonant cavities.

Therefore, there is an urgent need for a display panel and a mobile terminal to solve the above-described technical problems.

### SUMMARY OF INVENTION

### Technical Problem

Existing display panels with resonant cavities have poor viewing angles.

### Problem Solution

### Technical Solution

An embodiment of the present disclosure provides a display panel, including: a substrate and a light-emitting device, the substrate has a viewing angle adjustment structure near a light exit side of the light-emitting device, the light-emitting device includes a first electrode, a second electrode and a light-emitting functional layer arranged between the first electrode and the second electrode, the viewing angle adjustment structure corresponds to the light-emitting functional layer, the viewing angle adjustment structure includes a first refractive index layer and a second refractive index layer, the first refractive index layer includes a plurality of grooves, the second refractive index layer includes a plurality of protrusions. Each protrusion corresponds to each groove;
in which a refractive index of the second refractive index layer is less than a refractive index of the first refractive index layer.

In the display panel provided by an embodiment of the present disclosure, the display panel further includes a buffer layer, the buffer layer is arranged on a first substrate, the light-emitting device is arranged on the buffer layer;
in which one of films namely the first substrate and the buffer layer is provided with the plurality of grooves, and the other of the films namely the first substrate and the buffer layer is provided with the plurality of protrusions.

In the display panel provided by an embodiment of the present disclosure, the display panel further includes a buffer layer and an interlayer insulation layer, the buffer layer is arranged on a first substrate, the interlayer insulation layer is arranged on the buffer layer, the light-emitting device is arranged on the interlayer insulation layer;
in which one of films namely the buffer layer and the interlayer insulation layer is provided with the plurality of grooves, and the other of the films namely the buffer layer and the interlayer insulation layer is provided with the plurality of protrusions.

In the display panel provided by an embodiment of the present disclosure, the display panel further includes a buffer layer, an interlayer insulation layer, a passivation layer, and a planarization layer, the buffer layer is arranged on a first substrate, the interlayer insulation layer is arranged on the buffer layer, the passivation layer is arranged on the interlayer insulation layer, the planarization layer is arranged on the passivation layer, the light-emitting device is arranged on the planarization layer;
in which one of films namely the interlayer insulation layer and the passivation layer is provided with the plurality of grooves, and the other of the films namely the interlayer insulation layer and the passivation layer is provided with the plurality of protrusions.

In the display panel provided by an embodiment of the present disclosure, the display panel further includes an encapsulation layer, the substrate includes a second substrate and a third substrate, the light-emitting device is arranged on the second substrate, the encapsulation layer is arranged on the light-emitting device, the third substrate is arranged on the encapsulation layer;
in which one of films namely the encapsulation layer and the third substrate is provided with the plurality of grooves, and the other of the films namely the encapsulation layer and the third substrate is provided with the plurality of protrusions.

In the display panel provided by an embodiment of the present disclosure, every two adjacent protrusions are at equal intervals and all the protrusions have the same length.

In the display panel provided by an embodiment of the present disclosure, the length of the protrusions is greater than or equal to 2 um and less than or equal to the size of each sub-pixel in the display panel.

In the display panel provided by an embodiment of the present disclosure, the height of the protrusions is the same as the depth of the grooves. An embodiment of the present disclosure also provides a display panel, including: a substrate and a light-emitting device, the substrate has a viewing angle adjustment structure near a light exit side of the light-emitting device, the viewing angle adjustment structure includes a first refractive index layer and a second refractive index layer, the first refractive index layer includes a plurality of grooves, the second refractive index layer includes a plurality of protrusions, each protrusion corresponds to each groove;
in which a refractive index of the second refractive index layer is less than a refractive index of the first refractive index layer.

In the display panel provided by an embodiment of the present disclosure, the display panel further includes a buffer layer, the buffer layer is arranged on a first substrate, the light-emitting device is arranged on the buffer layer;
in which one of films namely the first substrate and the buffer layer is provided with the plurality of grooves, and the other of the films namely the first substrate and the buffer layer is provided with the plurality of protrusions.

In the display panel provided by an embodiment of the present disclosure, the display panel further includes a buffer layer and an interlayer insulation layer, the buffer layer is arranged on a first substrate, the interlayer insulation layer is arranged on the buffer layer, the light-emitting device is arranged on the interlayer insulation layer;
in which one of films namely the buffer layer and the interlayer insulation layer is provided with the plurality of grooves, and the other of the films namely the buffer layer and the interlayer insulation layer is provided with the plurality of protrusions.

In the display panel provided by an embodiment of the present disclosure, the display panel further includes a buffer layer, an interlayer insulation layer, a passivation layer, and a planarization layer, the buffer layer is arranged on a first substrate, the interlayer insulation layer is arranged on the buffer layer, the passivation layer is arranged on the interlayer insulation layer, the planarization layer is arranged on the passivation layer, the light-emitting device is arranged on the planarization layer;
in which one of films namely the interlayer insulation layer and the passivation layer is provided with the plurality of grooves, and the other of the films namely the interlayer insulation layer and the passivation layer is provided with the plurality of protrusions.

In the display panel provided by an embodiment of the present disclosure, the display panel further includes an encapsulation layer, the substrate includes a second substrate and a third substrate, the light-emitting device is arranged on the second substrate, the encapsulation layer is arranged on the light-emitting device, the third substrate is arranged on the encapsulation layer;
in which one of films namely the encapsulation layer and the third substrate is provided with the plurality of grooves, and the other of the films namely the encapsulation layer and the third substrate is provided with the plurality of protrusions.

In the display panel provided by an embodiment of the present disclosure, every two adjacent protrusions are at equal intervals and all the protrusions have the same length.

In the display panel provided by an embodiment of the present disclosure, the length of the protrusions is greater than or equal to 2 um and less than or equal to the size of each sub-pixel in the display panel.

In the display panel provided by an embodiment of the present disclosure, the height of the protrusions is the same as the depth of the grooves.

Accordingly, an embodiment of the present disclosure also provides a mobile terminal, including a terminal body and a display panel, the terminal body and the display panel are integrated;
in which the display panel includes: a substrate and a light-emitting device, the substrate has a viewing angle adjustment structure near a light exit side of the light-emitting device, the viewing angle adjustment structure includes a first refractive index layer and a second refractive index layer, the first refractive index layer includes a plurality of grooves, the second refractive index layer includes a plurality of protrusions, each protrusion corresponds to each groove;
in which a refractive index of the second refractive index layer is less than a refractive index of the first refractive index layer.

In the display panel provided by an embodiment of the present disclosure, the display panel further includes a buffer layer, the buffer layer is arranged on a first substrate, the light-emitting device is arranged on the buffer layer;
in which one of films namely the first substrate and the buffer layer is provided with the plurality of grooves, and the other of the films namely the first substrate and the buffer layer is provided with the plurality of protrusions.

In the display panel provided by an embodiment of the present disclosure, the display panel further includes a buffer layer and an interlayer insulation layer, the buffer layer is arranged on a first substrate, the interlayer insulation layer is arranged on the buffer layer, the light-emitting device is arranged on the interlayer insulation layer;
in which one of films namely the buffer layer and the interlayer insulation layer is provided with the plurality of grooves, and the other of the films namely the buffer layer and the interlayer insulation layer is provided with the plurality of protrusions.

In the display panel provided by an embodiment of the present disclosure, the display panel further includes a buffer layer, an interlayer insulation layer, a passivation layer, and a planarization layer, the buffer layer is arranged on a first substrate, the interlayer insulation layer is arranged on the buffer layer, the passivation layer is arranged on the interlayer insulation layer, the planarization layer is arranged on the passivation layer, the light-emitting device is arranged on the planarization layer;
in which one of films namely the interlayer insulation layer and the passivation layer is provided with the plurality of grooves, and the other of the films namely the interlayer insulation layer and the passivation layer is provided with the plurality of protrusions.

### Beneficial Effects of Invention

### Beneficial Effects

The embodiments of the present disclosure provide a display panel and a mobile terminal. The display panel includes a substrate and a light-emitting device. The substrate has a viewing angle adjustment structure near a light exit side of the light-emitting device. The viewing angle adjustment structure includes a first refractive index layer and a second refractive index layer. The first refractive index layer includes a plurality of grooves. The second refractive index layer includes a plurality of protrusions. Each protrusion corresponds to each groove. A refractive index of the second refractive index layer is less than a refractive index of the first refractive index layer. The above-described display panel is provided with a viewing angle adjustment structure on a light-emitting side of a light-emitting device. The viewing angle adjustment structure includes a first refractive index layer having a plurality of grooves and a second refractive index layer having a plurality of protrusions. Each protrusion corresponds to each groove, and a refractive index of the second refractive index layer is less than a refractive index of the first refractive index layer, so that light emitted by the light-emitting device undergoes a diffuse refraction phenomenon at an interface between the first refractive index layer and the second refractive index layer, thereby improving a display viewing angle of the display panel and further improving a display effect of the display panel.

### BRIEF DESCRIPTION OF DRAWINGS

### Description of Drawings

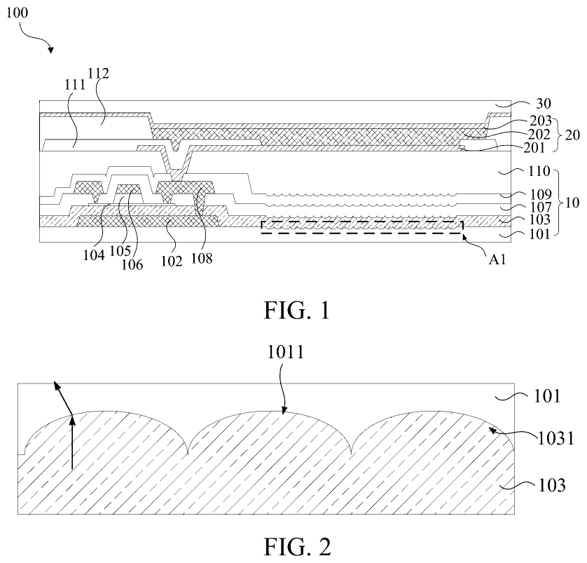

FIG. 1 is a cross-sectional structure diagram of a display panel according to a first embodiment of the present disclosure.

FIG. 2 is a schematic enlarged view of a display panel corresponding to part A1 in FIG. 1 according to a first embodiment of the present disclosure.

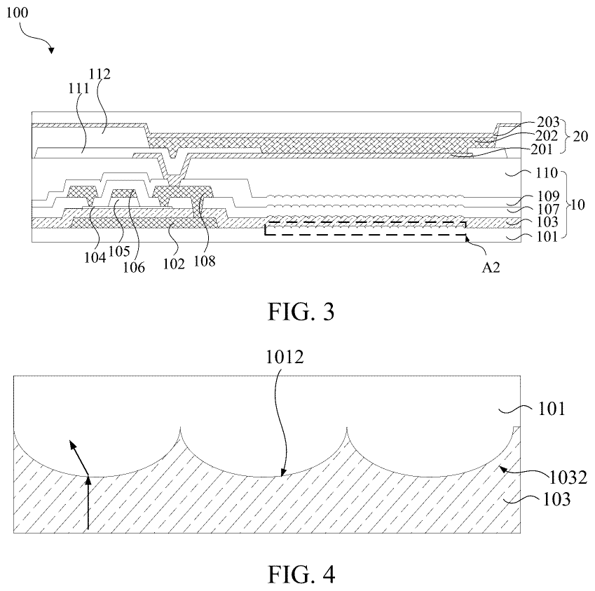

FIG. 3 is a cross-sectional structure diagram of a display panel according to a second embodiment of the present disclosure.

FIG. 4 is a schematic enlarged view of a display panel corresponding to part A2 in FIG. 3 according to a second embodiment of the present disclosure.

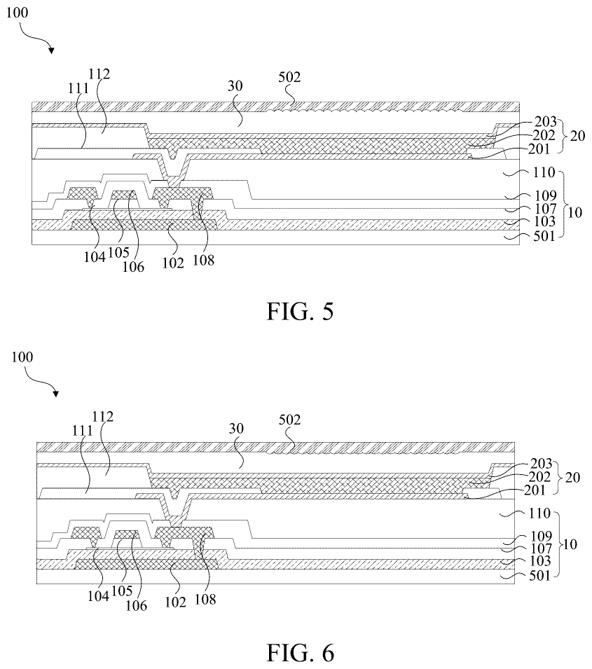

FIG. 5 is a cross-sectional structure diagram of a display panel according to a third embodiment of the present disclosure.

FIG. 6 is a cross-sectional structure diagram of a display panel according to a fourth embodiment of the present disclosure.

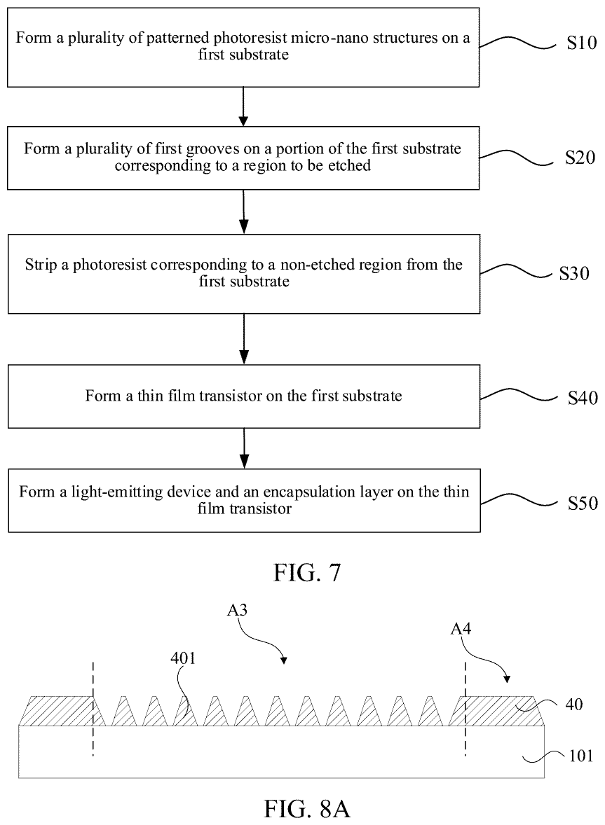

FIG. 7 is a flowchart of a preparation method of a display panel according to an embodiment of the present disclosure.

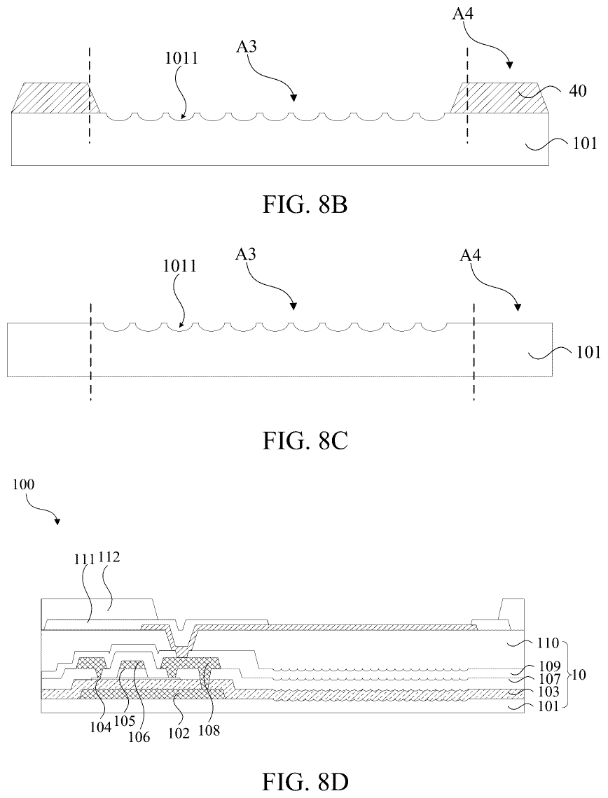

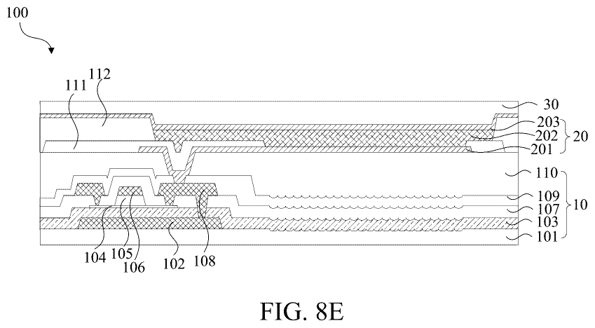

FIGS. 8A-8E are structure diagrams of a preparation method of a display panel according to an embodiment of the present disclosure.

### EMBODIMENTS OF INVENTION

### Implementation of the Present Invention

Embodiments of the present disclosure aim at the technical problem that a viewing angle of a current display panel is poor, and the embodiments of the present disclosure can improve the above-described technical problem.

Referring to FIGS. 1 to 6, an embodiment of the present disclosure provides a display panel 100, including a substrate and a light-emitting device 20. The substrate has a viewing angle adjustment structure near a light exit side of the light-emitting device 20. The viewing angle adjustment structure includes a first refractive index layer and a second refractive index layer. The first refractive index layer includes a plurality of grooves. The second refractive index layer includes a plurality of protrusions. Each protrusion corresponds to each groove.

A refractive index of the second refractive index layer is less than a refractive index of the first refractive index layer.

According to an embodiment of the present disclosure, a viewing angle adjustment structure is arranged on a light-emitting side of the light-emitting device 20. The viewing angle adjustment structure includes a first refractive index layer having a plurality of grooves and a second refractive index layer having a plurality of protrusions. Each protrusion corresponds to each groove, and a refractive index of the second refractive index layer is less than a refractive index of the first refractive index layer, so that light emitted by the light-emitting device 20 undergoes a diffuse refraction phenomenon at an interface between the first refractive index layer and the second refractive index layer, thereby improving a display viewing angle of the display panel 100 and further improving a display effect of the display panel 100. The technical solutions of the present disclosure are described below with reference to detailed embodiments.

### Embodiment 1

A cross-sectional structure diagram of a display panel 100 according to a first embodiment of the present disclosure is shown in FIG. 1. The display panel 100 provided by the present embodiment includes an array structure layer 10, a light-emitting device 20 arranged on the array structure layer 10, and an encapsulation layer 30 arranged on the light-emitting device 20.

In an embodiment of the present disclosure, the array structure layer 10 includes a first substrate 101, a light-shielding layer 102 arranged on the first substrate 101, a buffer layer 103 arranged on the first substrate 101 and completely covering the light-shielding layer 102, an active layer 104 arranged on the buffer layer 103, a gate insulation layer 105 arranged on the active layer 104, a gate metal layer 106 arranged on the gate insulation layer 105, an interlayer insulation layer 107 arranged on the buffer layer 103 and completely covering the active layer 104, the gate insulation layer 105 and the gate metal layer 106, a source-drain metal layer 108 arranged on the interlayer insulation layer 107, a passivation layer 109 arranged on the interlayer insulation layer 107 and completely covering the source-drain metal layer 108, a planarization layer 110 arranged on the passivation layer 109, a first pixel definition layer 111 arranged on the planarization layer 110, and a second pixel definition layer 112 arranged on the first pixel definition layer 111.

The source-drain metal layer 108 is electrically connected to a first end of the active layer 104 through a first via. The source-drain metal layer 108 is electrically connected to a second end of the active layer 104 through a second via. The source-drain metal layer 108 is also electrically connected to the light-shielding layer 102 through a third via.

In an embodiment of the present disclosure, the light-emitting device 20 includes a first electrode 201 arranged on the planarization layer 110, a light-emitting functional layer 202 arranged on the first electrode 201, and a second electrode 203 arranged on the light-emitting functional layer 202. The first electrode 201 is electrically connected to the source-drain metal layer 108 through a fourth via.

In an embodiment of the present disclosure, the viewing angle adjustment structure corresponds to the light-emitting functional layer 202.

Specifically, the first substrate 101 is a glass substrate. The buffer layer 103 is composed of one or a stack structure consisting of two or more of a silicon-containing nitride, a silicon-containing oxide or a silicon-containing oxynitride. The active layer 104 includes a channel region and doped regions. The doped regions are located on both sides of the channel region. The active layer 104 may be an oxide active layer or a low-temperature polycrystalline silicon active layer. For example, in some embodiments, the material of the active layer 104 is indium tin oxide, or Ln-IZO, ITZO, ITGZO, HIZO, IZO(InZnO), ZnO:F, In₂O₃:Sn, In₂O₃:Mo, Cd₂SnO₄, ZnO:Al, TiO₂:Nb, Cd—Sn—O, or other metal oxides. The doped region may be a P-type doped region or an N-type doped region. When the doped region is a P-type doped region, a doping element of the doped region is one or a mixture of two of boron and indium. When the doped region is an N-type doped region, a doping element of the doped region is one or a mixture of phosphorus, arsenic and antimony.

Further, the material of the gate insulation layer 105 may be one or any combination of silicon nitride, silicon oxide, silicon oxynitride, or aluminum oxide.

The material of the gate metal layer 106 may be selected from metals or alloys such as Cr, W, Ti, Ta, Mo, Al, and Cu, and the gate metal layer 106 composed of a plurality of layers of metals can also meet the requirements.

The material of the interlayer insulation layer 107 may be selected from an oxide or an oxynitride.

The source-drain metal layer 108 is electrically connected to the doped regions located on both sides of the channel region, respectively. A source and a drain may be selected from metals or alloys such as Cr, W, Ti, Ta, Mo, Al, and Cu, and a source-drain metal composed of a plurality of layers of metals can also meet the requirements.

The material of the passivation layer 109 may be a SiOₓ, SiOₓ/SiNₓ laminated or SiOₓ/SiNₓ/Al₂O₃ laminated inorganic non-metal film material.

The encapsulation layer 30 is arranged on the light-emitting device 20, and the encapsulation layer 30 is used for blocking the corrosion of the light-emitting device by external water and oxygen.

Further, the display panel 100 is a display panel 100 of a bottom emission structure. An exit direction of exit light of the display panel 100 is from the light-emitting device 20 to the first substrate 101. At this moment, the material of the first electrode 201 is transparent indium tin oxide.

A schematic enlarged view of a display panel corresponding to part A1 in FIG. 1 according to a first embodiment of the present disclosure is shown in FIG. 2. The surface of a side of the first substrate 101 near the buffer layer 103 is provided with a plurality of first grooves 1011. The surface of a side of the buffer layer 103 near the first substrate 101 is provided with a plurality of first protrusions 1031. Each of the first grooves 1011 is in one-to-one correspondence with each of the first protrusions 1031.

A protrusion direction of the first protrusions 1031 is opposite to the exit direction of the exit light.

In an embodiment of the present disclosure, the first substrate 101 has a viewing angle adjustment structure near a light exit side of the light-emitting device 20. The viewing angle adjustment structure includes a first refractive index layer and a second refractive index layer. The second refractive index layer is the first substrate 101. The first refractive index layer is the buffer layer 103. A refractive index of the buffer layer 103 is less than a refractive index of the first substrate 101. Specifically, every two adjacent first protrusions 1031 are at equal intervals, and all the first protrusions 1031 have the same size. With the current state of the photolithography technique, a minimum diameter of the first protrusions 1031 can be 2 um, and a maximum diameter cannot exceed the size of sub-pixels in the display panel 100.

Further, the height of the first protrusions 1031 is the same as the depth of the first grooves 1011. In this way, a gap is prevented from existing at an interface between the first substrate 101 and the first protrusions 1031, thereby preventing external moisture from invading the display panel 100 through the gap.

In an embodiment of the present disclosure, since the buffer layer 103, the interlayer insulation layer 107 and the passivation layer 109 are all prepared by a chemical vapor deposition method, the buffer layer 103, the interlayer insulation layer 107 and the passivation layer 109 have the same thickness at different positions.

Further, since the first substrate 101 is provided with the plurality of first grooves 1011, the surface of a side of the buffer layer 103 away from the first substrate 101 is provided with a plurality of second sub-grooves at positions corresponding to the first grooves 1011. The second sub-grooves are mainly formed due to the lower terrain of the positions on the buffer layer 103 corresponding to the first grooves 1011. By the same reasoning, the surface of a side of the interlayer insulation layer 107 near the buffer layer 103 is provided with a plurality of second sub-protrusions. Each of the second sub-protrusions corresponds to each of the second sub-grooves. The surface of a side of the interlayer insulation layer 107 away from the buffer layer 103 is provided with a plurality of third sub-grooves. Each of the third sub-grooves corresponds to each of the second sub-grooves. The surface of a side of the passivation layer 109 near the interlayer insulation layer 107 is provided with a plurality of third sub-protrusions. Each of the third sub-protrusions corresponds to each of the third sub-grooves. The surface of a side of the passivation layer 109 away from the buffer layer 103 is provided with a plurality of fourth sub-grooves. Each of the fourth sub-grooves corresponds to each of the third sub-grooves.

Furthermore, the surface of a side of the planarization layer 110 near the passivation layer 109 is provided with a plurality of fourth sub-protrusions. Each of the fourth sub-protrusions corresponds to each of the fourth sub-grooves. Since the planarization layer 110 is prepared in order to eliminate the unevenness of the array structure layer 10 to obtain the flat first electrode 201, the light-emitting device 20 with a uniform thickness is obtained. If the light-emitting device 20 has a non-uniform thickness within the sub-pixels, a brightness difference may be caused in exit light emitted from the display panel 100. Therefore, a side of the planarization layer 110 away from the passivation layer 109 is provided with a groove. At this moment, the terrain formed by concave-convex micro-nano structures in the display panel 100 is filled. A mechanism by which the display panel 100 according to the first embodiment of the present disclosure can improve a display viewing angle is as follows:

When light emitted by the light-emitting device 20 passes through the second refractive index layer to reach the interface between the second refractive index layer and the first refractive index layer, since the refractive index of the second refractive index layer is less than the refractive index of the first refractive index layer, exit light is refracted at the interface between the second refractive index layer and the first refractive index layer. At this moment, since the second refractive index layer is provided with the plurality of first protrusions 1031 and the protrusion direction of the first protrusions 1031 is the same as the exit direction of the exit light of the display panel 100, when the exit light enters the first refractive index layer through the first protrusions 1031, a normal line of the exit light deviates from a certain angle. Meanwhile, since the refractive index of the second refractive index layer is less than the refractive index of the first refractive index layer, an angle of refraction of the exit light is less than an angle of incidence, thereby scattering the exit light to different angles.

On the other hand, since the display panel further includes a plurality of micro-structures composed of the plurality of second sub-grooves, the plurality of second sub-protrusions, the plurality of third sub-grooves, the plurality of third sub-protrusions, and the plurality of fourth sub-grooves, the plurality of micro-structures and the viewing angle adjustment structure are used together to adjust a viewing angle of the display panel 100, a display effect of the display panel 100 can be adjusted.

In an embodiment of the present disclosure, the first refractive index layer may be the buffer layer 103. At this moment, the second refractive index layer is the interlayer insulation layer 107. The refractive index of interlayer insulation layer 107 is less than the refractive index of the buffer layer 103.

In an embodiment of the present disclosure, the first refractive index layer may be the interlayer insulation layer 107. At this moment, the second refractive index layer is the passivation layer 109. The refractive index of passivation layer 109 is less than the refractive index of the interlayer insulation layer 107.

In view of the technical problem of a current technology that a display viewing angle of the display panel 100 is poor, an embodiment of the present disclosure provides a display panel 100. The display panel 100 includes a first substrate 101 and a light-emitting device 20. The first substrate 101 has a viewing angle adjustment structure near a light exit side of the light-emitting device 20. The viewing angle adjustment structure includes a first refractive index layer and a second refractive index layer. The second refractive index layer is the first substrate 101. The first refractive index layer is the buffer layer 103. The first substrate 101 includes a plurality of second protrusions 1012. The buffer layer 103 includes a plurality of second grooves 1032. Each of the second protrusions 1012 corresponds to each of the second grooves 1032, and a refractive index of the buffer layer 103 is greater than a refractive index of the first substrate 101. The above-described display panel 100 is provided with a viewing angle adjustment structure on a light-emitting side of the light-emitting device 20. The viewing angle adjustment structure includes a second refractive index layer having a plurality of grooves and a first refractive index layer having a plurality of protrusions. Each protrusion corresponds to each groove, and a refractive index of the second refractive index layer is greater than a refractive index of the first refractive index layer, so that light emitted by the light-emitting device 20 undergoes a diffuse refraction phenomenon at an interface between the second refractive index layer and the first refractive index layer, thereby improving a display viewing angle of the display panel 100 and further improving a display effect of the display panel 100.

### Embodiment 2

A cross-sectional structure diagram of a display panel 100 according to a second embodiment of the present disclosure is shown in FIG. 3. A schematic enlarged view of a display panel corresponding to part A2 in FIG. 3 according to a second embodiment of the present disclosure is shown in FIG. 4. It can be seen from FIGS. 4 and 3 that the structure of the display panel 100 in the second embodiment of the present disclosure is mostly the same as that of the first embodiment of the present disclosure, except that the surface of a side of the first substrate 101 near the buffer layer 103 is provided with the plurality of second protrusions 1012, the surface of a side of the buffer layer 103 near the first substrate 101 is provided with the plurality of second grooves 1032, and each of the second protrusions 1012 corresponds to each of the second grooves 1032.

A refractive index of the buffer layer 103 is greater than a refractive index of the first substrate 101. A protrusion direction of the second protrusions 1012 is opposite to an exit direction of the exit light.

In an embodiment of the present disclosure, the first refractive index layer is the buffer layer 103. The second refractive index layer is the first substrate 101. The first refractive index layer and the second refractive index layer constitute the viewing angle adjustment structure.

In an embodiment of the present disclosure, since the buffer layer 103, the interlayer insulation layer 107 and the passivation layer 109 are all prepared by a chemical vapor deposition method, the buffer layer 103, the interlayer insulation layer 107 and the passivation layer 109 have the same thickness at different positions.

Further, since the first substrate 101 is provided with the plurality of second protrusions 1012, the surface of a side of the buffer layer 103 away from the first substrate 101 is provided with a plurality of fifth sub-protrusions at positions corresponding to the second protrusions 1012. The fifth sub-protrusions are mainly formed due to the higher terrain of the positions on the buffer layer 103 corresponding to the second protrusions 1012.

By the same reasoning, the surface of a side of the interlayer insulation layer 107 near the buffer layer 103 is provided with a plurality of fifth sub-grooves. Each of the fifth sub-grooves corresponds to each of the fifth sub-protrusions. The surface of a side of the interlayer insulation layer 107 away from the buffer layer 103 is provided with a plurality of sixth sub-protrusions. Each of the sixth sub-protrusions corresponds to each of the fifth sub-protrusions.

The surface of a side of the passivation layer 109 near the interlayer insulation layer 107 is provided with a plurality of sixth sub-grooves. Each of the sixth sub-grooves corresponds to each of the sixth sub-protrusions. The surface of a side of the passivation layer 109 away from the buffer layer 103 is provided with a plurality of seventh sub-protrusions. Each of the seventh sub-protrusions corresponds to each of the sixth sub-protrusions.

Furthermore, the surface of a side of the planarization layer 110 near the passivation layer 109 is provided with a plurality of seventh sub-grooves. Each of the seventh sub-grooves corresponds to each of the sixth sub-protrusions. Since the planarization layer 110 is prepared in order to eliminate the unevenness of the array structure layer 10 to obtain the flat first electrode 201, the light-emitting device 20 with a uniform thickness is obtained. If the light-emitting device 20 has a non-uniform thickness within the sub-pixels, a brightness difference may be caused in exit light emitted from the display panel 100. Therefore, a side of the planarization layer 110 away from the passivation layer 109 is provided with a protrusion. At this moment, the terrain formed by concave-convex micro-nano structures in the display panel 100 is filled.

On the other hand, since the display panel further includes a plurality of micro-structures composed of the plurality of fifth sub-grooves, the plurality of sixth sub-protrusions, the plurality of sixth sub-grooves, the plurality of seventh sub-protrusions, and the plurality of seventh sub-grooves, the plurality of micro-structures and the viewing angle adjustment structure are used together to adjust a viewing angle of the display panel 100, a display effect of the display panel 100 can be adjusted.

In an embodiment of the present disclosure, the first refractive index layer may be the interlayer insulation layer 107. At this moment, the second refractive index layer is the buffer layer 103. The refractive index of interlayer insulation layer 107 is greater than the refractive index of the buffer layer 103.

In an embodiment of the present disclosure, the first refractive index layer may be the passivation layer 109. At this moment, the second refractive index layer is the interlayer insulation layer 107. The refractive index of passivation layer 109 is greater than the refractive index of the interlayer insulation layer 107. A mechanism by which the display panel 100 according to an embodiment of the present disclosure can improve a display viewing angle is as follows.

When light emitted by the light-emitting device 20 passes through the second refractive index layer to reach the interface between the second refractive index layer and the first refractive index layer, since the refractive index of the second refractive index layer is greater than the refractive index of the first refractive index layer, exit light is refracted at the interface between the second refractive index layer and the first refractive index layer. At this moment, since the first refractive index layer is provided with the plurality of second protrusions 1012 and the protrusion direction of the second protrusions 1012 is opposite to the exit direction of the exit light of the display panel 100, when the exit light enters the first refractive index layer through the second grooves 1032, a normal line of the exit light deviates from a certain angle. Meanwhile, since the refractive index of the second refractive index layer is greater than the refractive index of the first refractive index layer, an angle of refraction of the exit light is greater than an angle of incidence, thereby scattering the exit light to different angles.

In view of the technical problem of a current technology that a display viewing angle of the display panel 100 is poor, an embodiment of the present disclosure provides a display panel 100. The display panel 100 includes a first substrate 101 and a light-emitting device 20. The first substrate 101 has a viewing angle adjustment structure near a light exit side of the light-emitting device 20. The viewing angle adjustment structure includes a first refractive index layer and a second refractive index layer. The first refractive index layer is the first substrate 101. The second refractive index layer is the buffer layer 103. The first substrate 101 includes a plurality of first grooves 1011. The buffer layer 103 includes a plurality of first protrusions 1031. Each of the first protrusions 1031 corresponds to each of the first grooves 1011, and a refractive index of the buffer layer 103 is less than a refractive index of the first substrate 101. The above-described display panel 100 is provided with a viewing angle adjustment structure on a light-emitting side of the light-emitting device 20. The viewing angle adjustment structure includes a first refractive index layer having a plurality of grooves and a second refractive index layer having a plurality of protrusions. Each protrusion corresponds to each groove, and a refractive index of the second refractive index layer is less than a refractive index of the first refractive index layer, so that light emitted by the light-emitting device 20 undergoes a diffuse refraction phenomenon at an interface between the first refractive index layer and the second refractive index layer, thereby improving a display viewing angle of the display panel 100 and further improving a display effect of the display panel 100.

### Embodiment 3

A cross-sectional structure diagram of a display panel 100 according to a third embodiment of the present disclosure is shown in FIG. 5. The structure of the display panel 100 in the third embodiment of the present disclosure is mostly the same as that of the first embodiment of the present disclosure, except that the substrate includes a second substrate 501 and a third substrate 502, the light-emitting device 20 is arranged on the second substrate 501, the encapsulation layer 30 is arranged on the light-emitting device 20, and the third substrate 502 is arranged on the encapsulation layer 30.

The encapsulation layer 30 is provided with the plurality of grooves. The surface of a side of the third substrate 502 near the encapsulation layer 30 is provided with the plurality of protrusions. Each of the grooves corresponds to one of the protrusions.

In an embodiment of the present disclosure, the first refractive index layer is the third substrate 502. The second refractive index layer is the encapsulation layer 30. The first refractive index layer and the second refractive index layer constitute the viewing angle adjustment structure. The refractive index of the third substrate 502 is greater than the refractive index of the encapsulation layer 30.

Preferably, the material of the third substrate 502 is a glass cover plate.

Further, the display panel 100 is a display panel 100 of a top emission structure. An exit direction of exit light of the display panel 100 is from the light-emitting device 20 to the third substrate 502. At this moment, the material of the second electrode 203 is transparent indium tin oxide.

In view of the technical problem of a current technology that a display viewing angle of the display panel 100 is poor, an embodiment of the present disclosure provides a display panel 100. The display panel 100 includes a light-emitting device 20 and a viewing angle adjustment structure located on a side of the light-emitting device 20 away from the array structure layer 10. Exit light of the light-emitting device 20 is guided through the viewing angle adjustment structure. The viewing angle adjustment structure further includes the encapsulation layer 30 and the third substrate 502 arranged on the encapsulation layer 30. The encapsulation layer 30 is provided with the plurality of protrusions. The surface of a side of the third substrate 502 near the encapsulation layer 30 is provided with the plurality of grooves. Each of the grooves corresponds to one of the protrusions. The protrusion direction of the protrusions is the same as the exit direction of the exit light of the display panel 100. The refractive index of the third substrate 502 is greater than the refractive index of the encapsulation layer 30. The above-described display panel 100 is provided with a viewing angle adjustment structure on a light-emitting side of the light-emitting device 20. The viewing angle adjustment structure includes a first refractive index layer having a plurality of grooves and a second refractive index layer having a plurality of protrusions. Each protrusion corresponds to each groove, and a refractive index of the second refractive index layer is less than a refractive index of the first refractive index layer, so that light emitted by the light-emitting device 20 undergoes a diffuse refraction phenomenon at an interface between the first refractive index layer and the second refractive index layer, thereby improving a display viewing angle of the display panel 100 and further improving a display effect of the display panel 100.

### Embodiment 4

A cross-sectional structure diagram of a display panel 100 according to a fourth embodiment of the present disclosure is shown in FIG. 6. The structure of the display panel 100 in the fourth embodiment of the present disclosure is mostly the same as that of the third embodiment of the present disclosure, except that the viewing angle adjustment structure includes the first refractive index layer and the second refractive index layer, the first refractive index layer is the encapsulation layer 30, the second refractive index layer is the third substrate 502, and the refractive index of the third substrate 502 is less than the refractive index of the encapsulation layer 30.

The encapsulation layer 30 is provided with a plurality of grooves. The surface of a side of the third substrate 502 near the encapsulation layer 30 is provided with a plurality of protrusions. Each of the grooves corresponds to one of the protrusions. A protrusion direction of the protrusions is opposite to an exit direction of exit light of the display panel 100.

In view of the technical problem of a current technology that a display viewing angle of the display panel 100 is poor, an embodiment of the present disclosure provides a display panel 100. The display panel 100 includes a light-emitting device 20 and a viewing angle adjustment structure located on a side of the light-emitting device 20 away from the array structure layer 10. Exit light of the light-emitting device 20 is guided through the viewing angle adjustment structure. The viewing angle adjustment structure further includes the encapsulation layer 30 and the third substrate 502 arranged on the encapsulation layer 30. The encapsulation layer 30 is provided with the plurality of grooves. The surface of a side of the third substrate 502 near the encapsulation layer 30 is provided with the plurality of protrusions. Each of the grooves corresponds to one of the protrusions. The protrusion direction of the protrusions is opposite to the exit direction of the exit light of the display panel 100. The refractive index of the third substrate 502 is less than the refractive index of the encapsulation layer 30. The above-described display panel 100 is provided with a viewing angle adjustment structure on a light-emitting side of the light-emitting device 20. The viewing angle adjustment structure includes a first refractive index layer having a plurality of grooves and a second refractive index layer having a plurality of protrusions. Each protrusion corresponds to each groove, and a refractive index of the second refractive index layer is less than a refractive index of the first refractive index layer, so that light emitted by the light-emitting device 20 undergoes a diffuse refraction phenomenon at an interface between the first refractive index layer and the second refractive index layer, thereby improving a display viewing angle of the display panel 100 and further improving a display effect of the display panel 100.

A flowchart of a preparation method of a display panel 100 according to an embodiment of the present disclosure is shown in FIG. 7. Taking the preparation of the display panel 100 according to the first embodiment of the present disclosure as an example, the method includes the following steps.

At S10, a plurality of patterned photoresist micro-nano structures 401 are formed on a first substrate 101.

Specifically, S10 further includes the following operations.

Firstly, a first substrate 101 is provided. The first substrate 101 includes a region to be etched A3 and a non-etched region A4 located on both sides of the region to be etched A3. Then, a layer of photoresist 40 is coated on the first substrate 101, and the photoresist 40 extends from the region to be etched A3 to the non-etched region A4. Finally, a patterned photoresist micro-nano structure 401 is formed in the region to be etched A3 by a yellow light process, as shown in FIG. 8A.

At S20, a plurality of first grooves 1011 are formed on a portion of the first substrate 101 corresponding to the region to be etched A3.

Specifically, S20 further includes the following operations.

The portion of the first substrate 101 corresponding to the region to be etched A3 is etched, and the photoresist micro-nano structure 401 and a portion of the first substrate 101 are etched away. At this moment, the portion of the first substrate 101 corresponding to the region to be etched A3 forms a plurality of first grooves 1011, as shown in FIG. 8B.

At S30, a photoresist 40 corresponding to the non-etched region A4 is stripped from the first substrate 101.

Specifically, S30 further includes the following operations.

The photoresist 40 corresponding to the non-etched region A4 is stripped from the first substrate 101 by using a stripping process, as shown in FIG. 8C.

At S40, a thin film transistor is formed on the first substrate 101.

Specifically, S40 further includes the following operations.

Firstly, a light-shielding metal layer is formed on a portion of the first substrate 101 corresponding to the non-etched region A4. Then, a buffer layer 103 is formed on the first substrate 101, the buffer layer 103 completely covers the light-shielding metal layer and the plurality of first grooves 1011, and portions of the buffer layer 103 corresponding to the first grooves 1011 form a plurality of first protrusions 1031. Finally, an active layer 104, a gate insulation layer 105, a gate metal layer 106, an interlayer insulation layer 107, a source-drain metal layer 108, a passivation layer 109, and a planarization layer 110 are successively prepared on the buffer layer 103 to form a thin film transistor. At this moment, the plurality of first grooves 1011 on the first substrate 101 are in one-to-one correspondence with the plurality of first protrusions 1031 on the buffer layer 103, as shown in FIG. 8D.

In an embodiment of the present disclosure, since the buffer layer 103, the interlayer insulation layer 107 and the passivation layer 109 are all prepared by a chemical vapor deposition method, the buffer layer 103, the interlayer insulation layer 107 and the passivation layer 109 have the same thickness at different positions.

Further, since the first substrate 101 is provided with the plurality of first grooves 1011, the surface of a side of the buffer layer 103 away from the first substrate 101 is provided with a plurality of second sub-grooves at positions corresponding to the first grooves 1011. The second sub-grooves are mainly formed due to the lower terrain of the positions on the buffer layer 103 corresponding to the first grooves 1011. By the same reasoning, the surface of a side of the interlayer insulation layer 107 near the buffer layer 103 is provided with a plurality of second sub-protrusions. Each of the second sub-protrusions corresponds to each of the second sub-grooves. The surface of a side of the interlayer insulation layer 107 away from the buffer layer 103 is provided with a plurality of third sub-grooves. Each of the third sub-grooves corresponds to each of the second sub-grooves. The surface of a side of the passivation layer 109 near the interlayer insulation layer 107 is provided with a plurality of third sub-protrusions. Each of the third sub-protrusions corresponds to each of the third sub-grooves. The surface of a side of the passivation layer 109 away from the buffer layer 103 is provided with a plurality of fourth sub-grooves. Each of the fourth sub-grooves corresponds to each of the third sub-grooves.

Furthermore, the surface of a side of the planarization layer 110 near the passivation layer 109 is provided with a plurality of fourth sub-protrusions. Each of the fourth sub-protrusions corresponds to each of the fourth sub-grooves. Since the planarization layer 110 is prepared in order to eliminate the unevenness of the array structure layer 10 to obtain the flat first electrode 201, the light-emitting device 20 with a uniform thickness is obtained. If the light-emitting device 20 has a non-uniform thickness within the sub-pixels, a brightness difference may be caused in exit light emitted from the display panel 100. Therefore, a side of the planarization layer 110 away from the passivation layer 109 is provided with a groove. At this moment, the terrain formed by concave-convex micro-nano structures constituted by the plurality of sub-grooves and the plurality of sub-protrusions is filled.

At S50, a light-emitting device 20 and an encapsulation layer 30 are formed on the thin film transistor.

Firstly, a first electrode 201 is formed on the planarization layer 110, and the first electrode 201 is electrically connected to the source-drain metal layer 108. Then, a first pixel definition layer 111 and a second pixel definition layer 112 are successively prepared on the planarization layer 110. Then, a light-emitting functional layer 202 is prepared at an opening of the second pixel definition layer 112. Finally, a second electrode 203 and an encapsulation layer 30 are prepared on the light-emitting functional layer 202, as shown in FIG. 8E.

Accordingly, an embodiment of the present disclosure also provides a mobile terminal, including a terminal body and the display panel 100 as described in any one of the above. The terminal body and the display panel 100 are integrated. The mobile terminal has a wide application space in vehicle-mounted, mobile phone, PAD, computer and television products.

The embodiments of the present disclosure provide a display panel 100 and a mobile terminal. The display panel 100 includes a substrate and a light-emitting device 20. The substrate has a viewing angle adjustment structure near a light exit side of the light-emitting device 20. The viewing angle adjustment structure includes a first refractive index layer and a second refractive index layer. The first refractive index layer includes a plurality of grooves. The second refractive index layer includes a plurality of protrusions. Each protrusion corresponds to each groove. A refractive index of the second refractive index layer is less than a refractive index of the first refractive index layer. According to an embodiment of the present disclosure, a viewing angle adjustment structure is arranged on a light-emitting side of the light-emitting device 20. The viewing angle adjustment structure includes a first refractive index layer having a plurality of grooves and a second refractive index layer having a plurality of protrusions. Each protrusion corresponds to each groove, and a refractive index of the second refractive index layer is less than a refractive index of the first refractive index layer, so that light emitted by the light-emitting device 20 undergoes a diffuse refraction phenomenon at an interface between the first refractive index layer and the second refractive index layer, thereby improving a display viewing angle of the display panel 100 and further improving a display effect of the display panel 100.

The descriptions of the above embodiments have respective emphasis. For parts not described in detail in a certain embodiment, reference may be made to related descriptions of other embodiments.

A display panel 100 and a mobile terminal provided in the embodiments of the present disclosure are described above in detail. Although the principles and implementations of the present disclosure are described by using specific examples in this specification, the descriptions of the above embodiments are merely intended to help understand the method and the core idea of the method of the present disclosure. Meanwhile, a person of ordinary skill in the art may make modifications to the specific implementations and application range according to the idea of the present disclosure. In conclusion, the content of this specification is not construed as a limit on the present disclosure.

1. A display panel, comprising: a substrate and a light-emitting device, the substrate having a viewing angle adjustment structure near a light exit side of the light-emitting device, the light-emitting device comprising a first electrode, a second electrode and a light-emitting functional layer arranged between the first electrode and the second electrode, the viewing angle adjustment structure corresponding to the light-emitting functional layer and comprising a first refractive index layer and a second refractive index layer, wherein the first refractive index layer comprises a plurality of grooves, the second refractive index layer comprises a plurality of protrusions, and each protrusion is corresponding to each groove,
wherein a refractive index of the second refractive index layer is less than a refractive index of the first refractive index layer.

2. The display panel of claim 1, further comprising: a buffer layer arranged on a first substrate, the light-emitting device being arranged on the buffer layer,
wherein one of films namely the first substrate and the buffer layer is provided with the plurality of grooves, and the other of the films namely the first substrate and the buffer layer is provided with the plurality of protrusions.

3. The display panel of claim 1, further comprising: a buffer layer arranged on a first substrate and an interlayer insulation layer arranged on the buffer layer, wherein the light-emitting device is arranged on the interlayer insulation layer,
wherein one of films namely the buffer layer and the interlayer insulation layer is provided with the plurality of grooves, and the other of the films namely the buffer layer and the interlayer insulation layer is provided with the plurality of protrusions.

4. The display panel of claim 1, further comprising: a buffer layer arranged on a first substrate, an interlayer insulation layer arranged on the buffer layer, a passivation layer arranged on the interlayer insulation layer, and a planarization layer arranged on the passivation layer, wherein the light-emitting device is arranged on the planarization layer,
wherein one of films namely the interlayer insulation layer and the passivation layer is provided with the plurality of grooves, and the other of the films namely the interlayer insulation layer and the passivation layer is provided with the plurality of protrusions.

5. The display panel of claim 1, further comprising: an encapsulation layer, the substrate comprising a second substrate and a third substrate, wherein the light-emitting device is arranged on the second substrate, the encapsulation layer is arranged on the light-emitting device, and the third substrate is arranged on the encapsulation layer,
wherein one of films namely the encapsulation layer and the third substrate is provided with the plurality of grooves, and the other of the films namely the encapsulation layer and the third substrate is provided with the plurality of protrusions.

6. The display panel of claim 1, wherein every two adjacent protrusions are at equal intervals and all the protrusions have the same length.

7. The display panel of claim 6, wherein the length of the protrusions is greater than or equal to 2 um and less than or equal to the size of each sub-pixel in the display panel.

8. The display panel of claim 1, wherein the height of the protrusions is the same as the depth of the grooves.

9. A display panel, comprising: a substrate and a light-emitting device, the substrate having a viewing angle adjustment structure near a light exit side of the light-emitting device, the viewing angle adjustment structure comprising a first refractive index layer and a second refractive index layer, the first refractive index layer comprising a plurality of grooves, the second refractive index layer comprising a plurality of protrusions, and each protrusion corresponding to each groove,
wherein a refractive index of the second refractive index layer is less than a refractive index of the first refractive index layer.

10. The display panel of claim 9, further comprising: a buffer layer arranged on a first substrate, wherein the light-emitting device is arranged on the buffer layer,
wherein one of films namely the first substrate and the buffer layer is provided with the plurality of grooves, and the other of the films namely the first substrate and the buffer layer is provided with the plurality of protrusions.

11. The display panel of claim 9, further comprising: a buffer layer arranged on a first substrate and an interlayer insulation layer arranged on the buffer layer, wherein the light-emitting device is arranged on the interlayer insulation layer,
wherein one of films namely the buffer layer and the interlayer insulation layer is provided with the plurality of grooves, and the other of the films namely the buffer layer and the interlayer insulation layer is provided with the plurality of protrusions.

12. The display panel of claim 9, further comprising: a buffer layer arranged on a first substrate, an interlayer insulation layer arranged on the buffer layer, a passivation layer arranged on the interlayer insulation layer, and a planarization layer arranged on the passivation layer, wherein the light-emitting device is arranged on the planarization layer,
wherein one of films namely the interlayer insulation layer and the passivation layer is provided with the plurality of grooves, and the other of the films namely the interlayer insulation layer and the passivation layer is provided with the plurality of protrusions.

13. The display panel of claim 9, further comprising: an encapsulation layer, the substrate comprising a second substrate and a third substrate, wherein the light-emitting device is arranged on the second substrate, the encapsulation layer is arranged on the light-emitting device, and the third substrate is arranged on the encapsulation layer,
wherein one of films namely the encapsulation layer and the third substrate is provided with the plurality of grooves, and the other of the films namely the encapsulation layer and the third substrate is provided with the plurality of protrusions.

14. The display panel of claim 9, wherein every two adjacent protrusions are at equal intervals and all the protrusions have the same length.

15. The display panel of claim 14, wherein the length of the protrusions is greater than or equal to 2 um and less than or equal to the size of each sub-pixel in the display panel.

16. The display panel of claim 9, wherein the height of the protrusions is the same as the depth of the grooves.

17. A mobile terminal, comprising: a terminal body and a display panel, which are integrated,
wherein the display panel comprises: a substrate and a light-emitting device, the substrate has a viewing angle adjustment structure near a light exit side of the light-emitting device, the viewing angle adjustment structure comprises a first refractive index layer and a second refractive index layer, the first refractive index layer comprises a plurality of grooves, the second refractive index layer comprises a plurality of protrusions, and each protrusion corresponds to each groove; and
a refractive index of the second refractive index layer is less than a refractive index of the first refractive index layer.

18. The mobile terminal of claim 17, wherein the display panel further comprises a buffer layer arranged on a first substrate, and the light-emitting device is arranged on the buffer layer; and
one of films namely the first substrate and the buffer layer is provided with the plurality of grooves, and the other of the films namely the first substrate and the buffer layer is provided with the plurality of protrusions.

19. The mobile terminal of claim 17, wherein the display panel further comprises a buffer layer arranged on a first substrate and an interlayer insulation layer arranged on the buffer layer, and the light-emitting device is arranged on the interlayer insulation layer; and
one of films namely the buffer layer and the interlayer insulation layer is provided with the plurality of grooves, and the other of the films namely the buffer layer and the interlayer insulation layer is provided with the plurality of protrusions.

20. The mobile terminal of claim 17, wherein the display panel further comprises a buffer layer arranged on a first substrate, an interlayer insulation layer arranged on the buffer layer, a passivation layer arranged on the interlayer insulation layer, and a planarization layer arranged on the passivation layer, and the light-emitting device is arranged on the planarization layer; and
one of films namely the interlayer insulation layer and the passivation layer is provided with the plurality of grooves, and the other of the films namely the interlayer insulation layer and the passivation layer is provided with the plurality of protrusions.
